(19) United States
(12) Patent Application Publication
(10) Pub. No.: US 2021/0181574 A1
(43) Pub. Date: Jun. 17, 2021

(54) COLOR CORRECTION MEMBER AND OPTICAL FILM USING COLOR CORRECTION MEMBER

(71) Applicant: NITTO DENKO CORPORATION, Ibaraki-shi, Osaka (JP)

(72) Inventors: Kozo Nakamura, Ibaraki-shi (JP); Takahiro Yoshikawa, Ibaraki-shi (JP); Yufeng Weng, Ibaraki-shi (JP); Peng Wang, San Diego, CA (US); Michael Welch, San Diego, CA (US); Shijun Zheng, San Diego, CA (US)

(73) Assignee: NITTO DENKO CORPORATION, Ibaraki-shi, Osaka (JP)

(21) Appl. No.: 16/767,720

(22) PCT Filed: Nov. 29, 2018
(86) PCT No.: PCT/JP2018/043982

§ 371 Date: May 28, 2020

Related U.S. Application Data
(60) Provisional application No. 62/592,270, filed on Nov. 29, 2017.

(51) Int. Cl. G02F 1/1335; C09J 133/06; C09J 7/38; H01L 51/50

(52) U.S. Cl. CPC G02F 1/133528; C09J 133/06; G02F 2202/28; H01L 51/50; C09J 2301/302; C09J 7/38

(57) ABSTRACT

An investigation made by the inventors has found that when the pressure-sensitive adhesive layer having incorporated thereinto tetraazaporphyrin is used as a color correction member, the layer absorbs light having a wavelength around 545 nm, and hence the brightness of a panel including the layer reduces. A color correction member is disclosed that can satisfactorily achieve both of the widening of the color gamut of an image display apparatus and the prevention of a reduction in brightness thereof. A color correction member, which is characterized in that, when a value of an absorption peak at from 580 nm to 610 nm of an absorption spectrum is represented by Aₘₐₓ, and a value of an absorbance at 545 nm of the absorption spectrum is represented by A₅₄₅, a ratio A₅₄₅/Aₘₐₓ is 0.13 or less.

### TECHNICAL FIELD

The present invention relates to a color correction member to be used in an optical film, an image display apparatus, or the like. The color correction member may form an image display apparatus, such as a liquid crystal display apparatus (LCD) or an organic EL display apparatus, alone or as an optical film obtained by laminating the member.

### BACKGROUND ART

In an image display apparatus or the like, because of its image-forming system, it is indispensable to arrange a polarizing element on each of both surfaces of a liquid crystal cell, and a polarizing film is generally bonded thereto. A pressure-sensitive adhesive is typically used at the time of the bonding of the polarizing film to the liquid crystal cell. In addition, at the time of the bonding of the polarizing film and the liquid crystal cell, the respective materials are typically brought into close contact with each other through the use of the pressure-sensitive adhesive for reducing the loss of light. In such case, a polarizing film with a pressure-sensitive adhesive layer obtained by arranging the pressure-sensitive adhesive as a pressure-sensitive adhesive layer on one surface of a polarizing film in advance is generally used because the polarizing film with a pressure-sensitive adhesive layer has, for example, the following merit. A drying step is not needed for fixing the polarizing film.

In addition, it has been proposed that a high-contrast liquid crystal display body be obtained by imparting any appropriate hue to the polarizing film through the coloring of the pressure-sensitive adhesive layer by the addition of a dye or a pigment thereto (Patent Literature 1). In recent years, the image display apparatus has been required to achieve lightness and vividness (i.e., color gamut widening), and hence an organic EL display apparatus (OLED) has been attracting attention. However, a liquid crystal display apparatus has also been required to achieve color gamut widening. For example, the following has been proposed as a method of widening the color gamut of the liquid crystal display apparatus (Patent Literatures 2 and 3). A polarizing film is laminated on one surface, or each of both surfaces, of the liquid crystal cell via a pressure-sensitive adhesive layer containing a coloring matter showing an absorption maximum wavelength in a specific wavelength range (from 560 nm to 610 nm).

### CITATION LIST

### Patent Literature

[PTL 1] JP 3052812 U

[PTL 2] JP 2011-039093 A

[PTL 3] JP 2014-092611 A

### SUMMARY OF INVENTION

### Technical Problem

When a coloring matter is incorporated into a pressure-sensitive adhesive layer like Patent Literatures 2 and 3, tetraazaporphyrin has heretofore been used as a coloring matter showing an absorption maximum wavelength in a specific wavelength range (from 560 nm to 610 nm). However, an investigation made by the inventors of the present invention has found that when the pressure-sensitive adhesive layer having incorporated thereinto tetraazaporphyrin is used as a color correction member, the layer absorbs light having a wavelength around 545 nm, and hence the brightness of a panel including the layer reduces.

An object of the present invention is to provide a color correction member that can satisfactorily achieve both of the widening of the color gamut of an image display apparatus and the prevention of a reduction in brightness thereof.

### Solution to Problem

The inventors of the present invention have made extensive investigations with a view to solving the problem, and as a result, have found the following color correction member. Thus, the inventors have completed the present invention. That is, the present invention lies in the following items [1] to [8].

[1] A color correction member, which is characterized in that, when a value of an absorption peak at from 580 nm to 610 nm of an absorption spectrum is represented by Aₘₐₓ, and a value of an absorbance at 545 nm of the absorption spectrum is represented by A₅₄₅, a ratio A₅₄₅/Aₘₐₓ is 0.13 or less,

provided that the absorption spectrum is obtained by: dispersing or dissolving the color correction member in an organic solvent to prepare a dispersion liquid or a solution; and measuring an absorbance of the dispersion liquid or the solution in a range of from 400 nm to 700 nm.

[2] The color correction member according to the above-mentioned item [1], wherein the color correction member is free of an absorption peak at from 530 nm to 570 nm of the absorption spectrum.

[3] The color correction member according to the above-mentioned item [1] or [2], wherein the absorption peak that the color correction member has at from 580 nm to 610 nm has a half width of 35 nm or less.

[4] The color correction member according to any one of the above-mentioned items [1] to [3], wherein the color correction member contains a compound represented by the following formula (I) or (II):

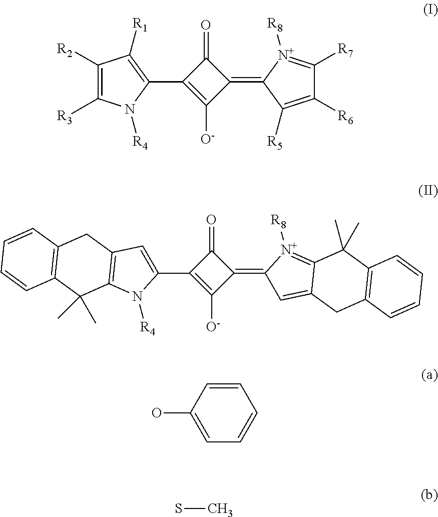

in the formula (I),

R₁, R₂, R₃, R₄, R₅, R₆, R₇, and R₈ each independently represent a hydrogen atom, a halogen atom, a substituted or unsubstituted alkyl group having 1 or more and 20 or less carbon atoms, a substituent represented by the formula (a), or a substituent represented by the formula (b),

R₁ and R₂ form a saturated cyclic skeleton including 5 or 6 carbon atoms, and R₃, R₄, R₅, R₆, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),

R₂ and R₃ form a saturated cyclic skeleton including 5 to 7 carbon atoms, and R₁, R₄, R₅, R₆, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),

R₅ and R₆ form a saturated cyclic skeleton including 5 or 6 carbon atoms, and R₁, R₂, R₃, R₄, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),

R₆ and R₇ form a saturated cyclic skeleton including 5 to 7 carbon atoms, and R₁, R₂, R₃, R₄, R₅, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),

R₁ and R₂ form a saturated cyclic skeleton including 5 or 6 carbon atoms, R₅ and R₆ form a saturated cyclic skeleton including 5 or 6 carbon atoms, and R₃, R₄, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b), or

R₂ and R₃ form a saturated cyclic skeleton including 5 to 7 carbon atoms, R₆ and R₇ form a saturated cyclic skeleton including 5 to 7 carbon atoms, and R₁, R₄, R₅, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b); and

in the formula (II), R₄ and R₈ each independently represent a hydrogen atom, or a substituted or unsubstituted alkyl group having 1 or more and 20 or less carbon atoms.

[5] An optical film, including:

a polarizing film; and

a pressure-sensitive adhesive layer,

wherein when a value of an absorption peak at from 580 nm to 610 nm of an absorption spectrum of the pressure-sensitive adhesive layer is represented by Aₘₐₓ, and a value of an absorbance at 545 nm of the absorption spectrum is represented by A₅₄₅, a ratio A₅₄₅/Aₘₐₓ is 0.13 or less,

provided that the absorption spectrum is obtained by: dispersing or dissolving the pressure-sensitive adhesive in an organic solvent to prepare a dispersion liquid or a solution; and measuring an absorbance of the dispersion liquid or the solution in a range of from 400 nm to 700 nm.

[6] The optical film according to the above-mentioned item [5], wherein the pressure-sensitive adhesive layer is free of an absorption peak at from 530 nm to 570 nm of the absorption spectrum.

[7] The optical film according to the above-mentioned item [5] or [6], wherein the absorption peak at from 580 nm to 610 nm has a half width of 35 nm or less.

[8] The optical film according to any one of the above-mentioned items [5] to [7], wherein the pressure-sensitive adhesive layer contains a compound represented by the following formula (I) or (II):

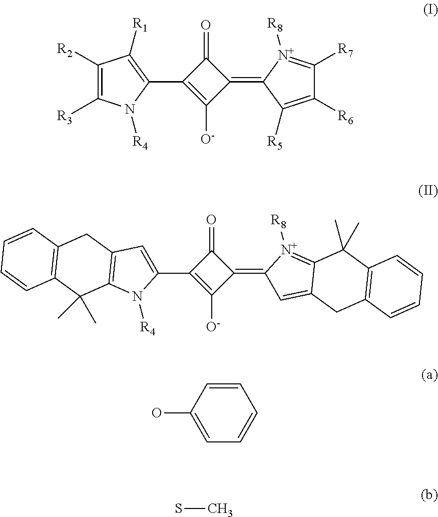

in the formula (I),

R₁, R₂, R₃, R₄, R₅, R₆, R₇, and R₈ each independently represent a hydrogen atom, a halogen atom, a substituted or unsubstituted alkyl group having 1 or more and 20 or less carbon atoms, a substituent represented by the formula (a), or a substituent represented by the formula (b),

R₁ and R₂ form a saturated cyclic skeleton including 5 or 6 carbon atoms, and R₃, R₄, R₅, R₆, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),

R₂ and R₃ form a saturated cyclic skeleton including 5 to 7 carbon atoms, and R₁, R₄, R₅, R₆, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),

R₅ and R₆ form a saturated cyclic skeleton including 5 or 6 carbon atoms, and R₁, R₂, R₃, R₄, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),

R₆ and R₇ form a saturated cyclic skeleton including 5 to 7 carbon atoms, and R₁, R₂, R₃, R₄, R₅, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),

R₁ and R₂ form a saturated cyclic skeleton including 5 or 6 carbon atoms, R₅ and R₆ form a saturated cyclic skeleton including 5 or 6 carbon atoms, and R₃, R₄, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b), or

R₂ and R₃ form a saturated cyclic skeleton including 5 to 7 carbon atoms, R₅ and R₇ form a saturated cyclic skeleton including 5 to 7 carbon atoms, and R₁, R₄, R₅, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b); and

in the formula (II), R₄ and R₈ each independently represent a hydrogen atom, or a substituted or unsubstituted alkyl group having 1 or more and 20 or less carbon atoms.

### Advantageous Effects of Invention

According to the present invention, the following effects are exhibited: the widening of the color gamut of an image display apparatus can be achieved; and moreover, the absorption of light having a wavelength around 545 nm is suppressed, and hence an improvement in brightness thereof, which has heretofore been impossible, can also be achieved.

### DESCRIPTION OF EMBODIMENTS

The present invention is described below. However, the present invention is not limited to the following embodiment, and may be carried out with any appropriate modification.

The form of a color correction member of the present invention is not particularly limited as long as the member has an absorption peak at from 580 nm to 610 nm of its absorption spectrum; and when the value of the highest absorption peak at from 580 nm to 610 nm of the absorption spectrum is represented by Aₘₐₓ, and the value of an absorbance at 545 nm of the absorption spectrum is represented by A₅₄₅, a ratio A₅₄₅/Aₘₐₓ satisfies a relationship of A₅₄₅/Aₘₐₓ≤0.13. For example, there is given a resin film containing a compound having an absorption peak at from 580 nm to 610 nm of its absorption spectrum; and when the value of the highest absorption peak at from 580 nm to 610 nm of the absorption spectrum is represented by Aₘₐₓ, and the value of an absorbance at 545 nm of the absorption spectrum is represented by A₅₄₅, a ratio A₅₄₅/Aₘₐₓ satisfies a relationship of A₅₄₅/Aₘₐₓ≤0.13. Another example thereof is an optical pressure-sensitive adhesive sheet containing the compound in its pressure-sensitive adhesive, and an optical film including the color correction member is, for example, an optical film including a pressure-sensitive adhesive layer containing the compound. The optical film is, for example, a polarizing film.

The color correction member of the present invention is described below by taking an optical pressure-sensitive adhesive sheet containing a compound having an absorption peak at from 580 nm to 610 nm of its absorption spectrum; and when the value of the highest absorption peak at from 580 nm to 610 nm of the absorption spectrum is represented by Aₘₐₓ, and the value of an absorbance at 545 nm of the absorption spectrum is represented by A₅₄₅, a ratio A₅₄₅/Aₘₐₓ satisfies a relationship of A₅₄₅/Aₘₐₓ0.13. In addition, an optical film of the present invention is described by taking, as examples, a polarizing film including a polyvinyl alcohol-based polarizer and a polarizing film with a pressure-sensitive adhesive layer including a pressure-sensitive adhesive layer containing the compound.

A. Color Correction Member

### A-1. Optical Pressure-Sensitive Adhesive Sheet

The optical pressure-sensitive adhesive sheet may be formed from a pressure-sensitive adhesive composition containing a base polymer and a compound X to be described later.

The optical pressure-sensitive adhesive sheet has an absorption peak at from 580 nm to 610 nm of its absorption spectrum, and when the value of the highest absorption peak at from 580 nm to 610 nm of the absorption spectrum is represented by Aₘₐₓ, and the value of the absorbance at 545 nm of the absorption spectrum is represented by A₅₄₅, the ratio A₅₄₅/Aₘₐₓ satisfies a relationship of A₅₄₅/Aₘₐₓ≤0.13. The absorption spectrum is obtained by: dispersing or dissolving the optical pressure-sensitive adhesive sheet in an organic solvent to prepare a dispersion liquid or a solution; and measuring the absorbance of the dispersion liquid or the solution in the range of from 400 nm to 700 nm. The optical pressure-sensitive adhesive sheet is preferably free of an absorption peak in the range of from 530 nm to 570 nm of the absorption spectrum. In addition, from the viewpoint of further widening of the color gamut of an image display apparatus, the half width of the absorption peak that the optical pressure-sensitive adhesive sheet has at from 580 nm to 610 nm of the absorption spectrum is more preferably 35 nm or less.

The kind of the base polymer is not particularly limited, and examples thereof include various polymers, such as a rubber-based polymer, a (meth)acrylic polymer, a silicone-based polymer, a urethane-based polymer, a vinyl alkyl ether-based polymer, a polyvinyl alcohol-based polymer, a polyvinylpyrrolidone-based polymer, a polyacrylamide-based polymer, and a cellulose-based polymer.

The optical pressure-sensitive adhesive sheet contains the base polymer as a main component. The main component refers to a component having the largest content out of the total solid content in the pressure-sensitive adhesive composition, and refers to, for example, a component accounting for more than 50 wt %, further a component accounting for more than 70 wt % of the total solid content in the pressure-sensitive adhesive composition.

Of those base polymers, there is preferably used a base polymer, which is excellent in optical transparency; the base polymer shows appropriate wettability, appropriate cohesiveness, and appropriate pressure-sensitive adhesive characteristics, such as an adhesive property; and the base polymer is excellent in weatherability, heat resistance, and the like. A (meth)acrylic polymer is preferably used as a base polymer showing such features. An acrylic pressure-sensitive adhesive containing, as a base polymer, a (meth)acrylic polymer containing an alkyl (meth)acrylate as a monomer unit, the pressure-sensitive adhesive serving as a formation material for the pressure-sensitive adhesive composition, is described below.

### A-2. (Meth)acrylic Polymer

The (meth)acrylic polymer typically contains, as a monomer unit, an alkyl (meth)acrylate serving as a main component. The (meth)acrylate means an acrylate and/or a methacrylate, which is the same meaning as (meth) of the present invention.

Examples of the alkyl (meth)acrylate for forming the main skeleton of the (meth)acrylic polymer may include alkyl (meth)acrylates each having a linear or branched alkyl group having 1 to 18 carbon atoms. Those alkyl (meth)acrylates may be used alone or in combination thereof. The average number of carbon atoms of those alkyl groups is preferably from 3 to 9.

One or more kinds of copolymerizable monomers each having a polymerizable functional group having an unsaturated double bond, such as a (meth)acryloyl group or a vinyl group, may be introduced into the (meth)acrylic polymer through copolymerization for the purpose of improving the adhesive property or heat resistance of the polymer.

The (meth)acrylic polymer contains the alkyl (meth)acrylate as a main component in the weight ratio of all of its constituent monomers. Although the ratio of the copolymerizable monomer in the (meth)acrylic polymer is not particularly limited, the ratio of the copolymerizable monomer is preferably from 0% to about 20%, more preferably from about 0.1% to about 15%, still more preferably from about 0.1% to about 10% in the weight ratio of all the constituent monomers.

A (meth)acrylic polymer having a weight-average molecular weight in the range of from 500,000 to 3,000,000 is typically used as the (meth)acrylic polymer of the present invention. A (meth)acrylic polymer having a weight-average molecular weight in the range of from 700,000 to 2,700,000 is preferably used in consideration of its durability, in particular, heat resistance. The weight-average molecular weight is more preferably from 800,000 to 2,500,000. A weight-average molecular weight of less than 500,000 is not preferred in terms of heat resistance. In addition, a weight-average molecular weight of more than 3,000,000 is not preferred because a large amount of a diluent solvent is needed for adjusting the viscosity of the polymer to a value suitable for application, thereby leading to an increase in cost. The weight-average molecular weight refers to a value measured by gel permeation chromatography (GPC) and calculated in terms of polystyrene.

Known production methods including solution polymerization, radiation polymerization, such as UV polymerization, bulk polymerization, emulsion polymerization, and various kinds of radical polymerization may each be appropriately selected for the production of such (meth)acrylic polymer. In addition, the (meth)acrylic polymer to be obtained may be anyone of, for example, a random copolymer, a block copolymer, and a graft copolymer.

In the solution polymerization, for example, ethyl acetate or toluene is used as a polymerization solvent. As a specific example of the solution polymerization, a reaction is performed by adding a polymerization initiator in a stream of an inert gas, such as nitrogen, typically under the reaction conditions of a temperature of from about 50° C. to about 70° C. and a time period of from about 5 hours to about 30 hours.

A polymerization initiator, a chain transfer agent, an emulsifying agent, or the like to be used in the radical polymerization is not particularly limited, and may be appropriately selected and used. The weight-average molecular weight of the (meth)acrylic polymer may be controlled by the usage amount of the polymerization initiator or the chain transfer agent, and reaction conditions, and the usage amount is appropriately adjusted in accordance with the kind thereof.

Examples of the radical polymerization initiator may include, but not limited to: azo-based initiators, such as 2,2′-azobisisobutyronitrile, 2,2′-azobis(2-amidinopropane) dihydrochloride, 2,2′-azobis[2-(5-methyl-2-imidazolin-2-yl)propane] dihydrochloride, 2,2′-azobis(2-methylpropionamidine) disulfate, 2,2′-azobis(N,N′-dimethyleneisobutylamidine), and 2,2′-azobis[N-(2-carboxyethyl)-2-methylpropionamidine] hydrate (manufactured by Wako Pure Chemical Industries, Ltd., VA-057); persulfates, such as potassium persulfate and ammonium persulfate; peroxide-based initiators, such as di(2-ethylhexyl) peroxydicarbonate, di(4-t-butylcyclohexyl) peroxydicarbonate, di-sec-butyl peroxydicarbonate, t-butyl peroxyneodecanoate, t-hexyl peroxypivalate, t-butyl peroxypivalate, dilauroyl peroxide, di-n-octanoyl peroxide, 1,1,3,3-tetramethylbutyl peroxy-2-ethylhexanoate, di(4-methylbenzoyl) peroxide, dibenzoyl peroxide, t-butyl peroxyisobutyrate, 1,1-di(t-hexylperoxy)cyclohexane, t-butyl hydroperoxide, and hydrogen peroxide; and redox-based initiators each formed by a combination of a peroxide and a reducing agent, such as a combination of a persulfate and sodium hydrogen sulfite and a combination of a peroxide and sodium ascorbate.

The radical polymerization initiators may be used alone or as a mixture thereof. The total content of the radical polymerization initiator is preferably from about 0.005 part by weight to about 1 part by weight, more preferably from about 0.02 part by weight to about 0.5 part by weight with respect to 100 parts by weight of the monomers.

Examples of the chain transfer agent include lauryl mercaptan, glycidyl mercaptan, mercaptoacetic acid, 2-mercaptoethanol, thioglycolic acid, 2-ethylhexyl thioglycolate, and 2,3-dimercapto-1-propanol. The chain transfer agents may be used alone or as a mixture thereof. The total content thereof is about 0.1 part by weight or less with respect to 100 parts by weight of the total amount of the monomer component.

In addition, examples of an emulsifying agent to be used in the emulsion polymerization include: anionic emulsifying agents, such as sodium lauryl sulfate, ammonium lauryl sulfate, sodium dodecylbenzene sulfonate, an ammonium polyoxyethylene alkyl ether sulfate, and a sodium polyoxyethylene alkyl phenyl ether sulfate; and nonionic emulsifying agents, such as a polyoxyethylene alkyl ether, a polyoxyethylene alkyl phenyl ether, a polyoxyethylene fatty acid ester, and a polyoxyethylene-polyoxypropylene block polymer. Those emulsifying agents may be used alone or in combination thereof.

Further, as a reactive emulsifying agent, there is given, for example, an emulsifying agent obtained by introducing a radical polymerizable functional group, such as a propenyl group or an allyl ether group. Specific examples thereof include Aqualon HS-10, HS-20, KH-10, BC-05, BC-10, and BC-20 (each of which is manufactured by DKS Co., Ltd.), and ADEKA REASOAP SE10N (manufactured by Asahi Denka Kogyo K.K.). The reactive emulsifying agent is preferred because the emulsifying agent is captured in the chain of the polymer after its polymerization, and hence the water resistance of the polymer is improved. The usage amount of the emulsifying agent is preferably from 0.3 part by weight to 5 parts by weight with respect to 100 parts by weight of the total amount of the monomer component, and is more preferably from 0.5 part by weight to 1 part by weight in terms of the polymerization stability and mechanical stability of the polymer.

### A-3. Compound X

The compound X to be incorporated into the optical pressure-sensitive adhesive sheet is not particularly limited as long as the compound which has an absorption peak at from 580 nm to 610 nm of its absorption spectrum; and when the value of the highest absorption peak at from 580 nm to 610 nm of the absorption spectrum is represented by Aₘₐₓ, and the value of the absorbance at 545 nm of the absorption spectrum is represented by A₅₄₅, the ratio A₅₄₅/Aₘₐₓ satisfies a relationship of A₅₄₅/Aₘₐₓ≤0.13.

The compound X is preferably free of an absorption peak in the range of from 530 nm to 570 nm of the absorption spectrum.

In addition, from the viewpoint of further widening of the color gamut of an image display apparatus, the half width of the absorption peak that the compound X has at from 580 nm to 610 nm of the absorption spectrum is more preferably 35 nm or less.

Examples of such compound X may include compounds each represented by the following formula (I) or (II).

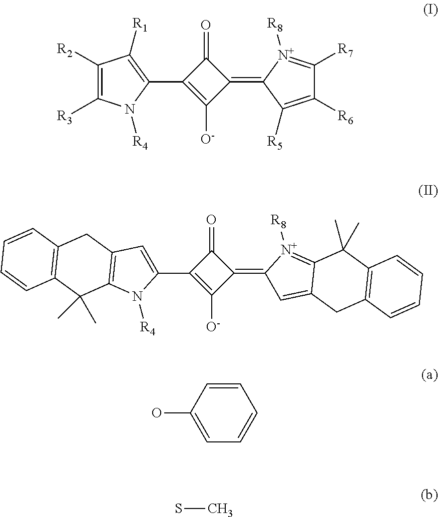

in the formula (I),

R₁, R₂, R₃, R₄, R₅, R₆, R₇, and R₈ each independently represent a hydrogen atom, a halogen atom, a substituted or unsubstituted alkyl group having 1 or more and 20 or less carbon atoms, a substituent represented by the formula (a), or a substituent represented by the formula (b),

R₁ and R₂ form a saturated cyclic skeleton including 5 or 6 carbon atoms, and R₃, R₄, R₅, R₆, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),

R₂ and R₃ form a saturated cyclic skeleton including 5 to 7 carbon atoms, and R₁, R₄, R₅, R₆, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),

R₅ and R₆ form a saturated cyclic skeleton including 5 or 6 carbon atoms, and R₁, R₂, R₃, R₄, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),

R₆ and R₇ form a saturated cyclic skeleton including 5 to 7 carbon atoms, and R₁, R₂, R₃, R₄, R₅, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),

R₁ and R₂ form a saturated cyclic skeleton including 5 or 6 carbon atoms, R₅ and R₆ form a saturated cyclic skeleton including 5 or 6 carbon atoms, and R₃, R₄, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b), or

R₂ and R₃ form a saturated cyclic skeleton including 5 to 7 carbon atoms, R₆ and R₇ form a saturated cyclic skeleton including 5 to 7 carbon atoms, and R₁, R₄, R₅, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b); and

in the formula (II), R₄ and R₈ each independently represent a hydrogen atom, or a substituted or unsubstituted alkyl group having 1 or more and 20 or less carbon atoms.

The saturated cyclic skeleton (number of carbon atoms: 5 or 6) formed so as to include R₁ and R₂, and the saturated cyclic skeleton (number of carbon atoms: 5 or 6) formed so as to include R₅ and R₆ may each have a substituent. The substituent is, for example, an alkyl group having 1 to 4 carbon atoms. In addition, the saturated cyclic skeleton (number of carbon atoms: 5 to 7) formed so as to include R₂ and R₃, and the saturated cyclic skeleton (number of carbon atoms: 5 to 7) formed so as to include R₆ and R₇ may each have a substituent. The substituent is, for example, an alkyl group having 1 to 4 carbon atoms.

In one embodiment, R₄ and/or R₈ has a benzene ring or a naphthalene ring as a substituent.

Specific examples of the compound X represented by the formula (I) or (II) include compounds represented by the following general formulae (I-1) to (I-27) and (II-1). The absorption peak of the compound X is shown in each of the following tables. With regard to each of the formulae (I-1) to (I-23), an absorption peak obtained by measuring the absorbance of a film formed of a resin composition prepared by mixing aliphatic polycarbonate with the compound X is shown, and with regard to each of the formulae (I-24) to (I-27) and (II-1), an absorption peak obtained by measuring the absorbance of a film formed of a resin composition prepared by mixing a polymethyl methacrylate resin with the compound X is shown.

| | | Absorption peak |
|---|---|---|
| NO. | Compound X | (nm) |
| I-1 | 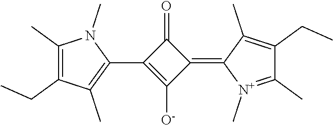 [SMILES: CCC1=C(C)/C(=C2\C(=O)C(c3c(C)c(CC)c(C)n3C)=C2[O-])[N+](C)=C1C] | 596 nm (APC) |
| I-2 | 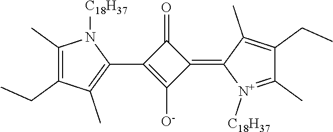 | 595 nm (APC) |
| I-3 | 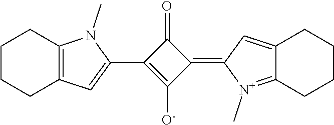 [SMILES: Cn1c(C2=C([O-])/C(=C3/C=C4CCCCC4=[N+]3C)C2=O)cc2c1CCCC2] | 582 nm (APC) |
| I-4 | 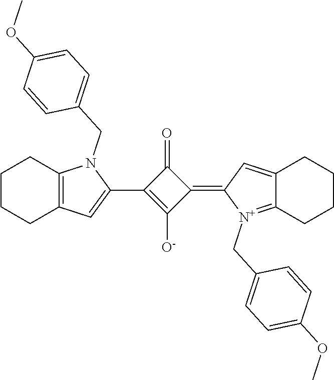 [SMILES: COc1ccc(Cn2c(C3=C([O-])/C(=C4/C=C5CCCCC5=[N+]4Cc4ccc(OC)cc4)C3=O)cc3c2CCCC3)cc1] | 585 nm (APC) |
| I-5 | 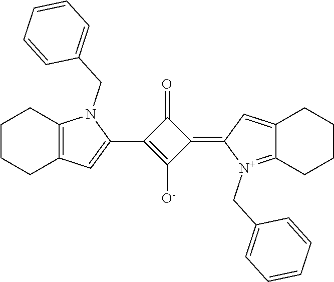 [SMILES: O=C1C(c2cc3c(n2Cc2ccccc2)CCCC3)=C([O-])/C1=C1/C=C2CCCCC2=[N+]1Cc1ccccc1] | 585 nm (APC) |
| I-6 | 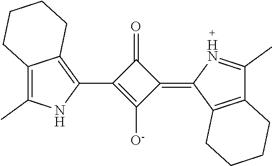 | 575 nm (APC) |
| I-7 | 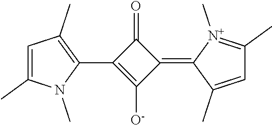 | 585 nm (APC) |
| I-8 | 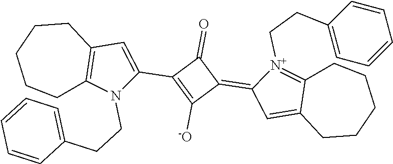 | 587 nm (APC) |
| I-9 | 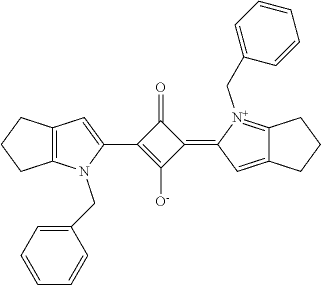 [SMILES: O=C1C(c2cc3c(n2Cc2ccccc2)CCC3)=C([O-])/C1=C1\C=C2CCCC2=[N+]1Cc1ccccc1] | 587 nm (APC) |
| I-10 | 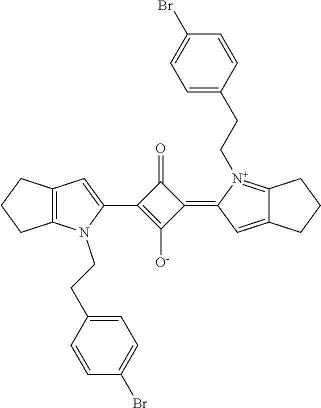 [SMILES: O=C1C(c2cc3c(n2CCc2ccc(Br)cc2)CCC3)=C([O-])/C1=C1\C=C2CCCC2=[N+]1CCc1ccc(Br)cc1] | 588 nm (APC) |
| I-11 | 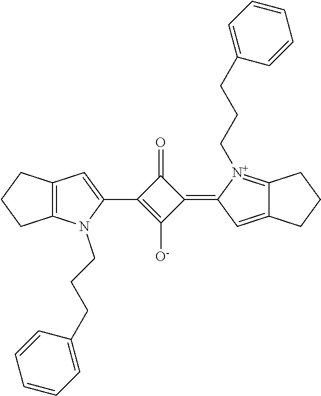 [SMILES: O=C1C(c2cc3c(n2CCCc2ccccc2)CCC3)=C([O-])/C1=C1\C=C2CCCC2=[N+]1CCCc1ccccc1] | 588 nm (APC) |
| I-12 | 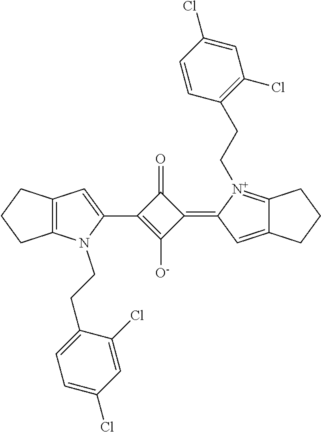 [SMILES: O=C1C(c2cc3c(n2CCc2ccc(Cl)cc2Cl)CCC3)=C([O-])/C1=C1\C=C2CCCC2=[N+]1CCc1ccc(Cl)cc1Cl] | 589 nm (APC) |
| I-13 | 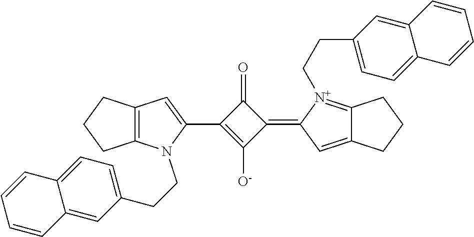 [SMILES: O=C1C(c2cc3c(n2CCc2ccc4ccccc4c2)CCC3)=C([O-])/C1=C1\C=C2CCCC2=[N+]1CCc1ccc2ccccc2c1] | 592 nm (APC) |
| I-14 | 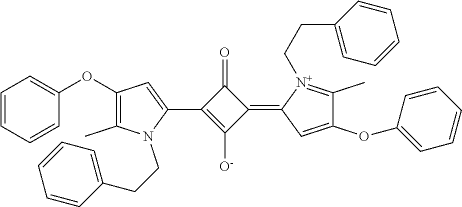 [SMILES: CC1=[N+](CCc2ccccc2)/C(=C2\C(=O)C(c3cc(Oc4ccccc4)c(C)n3CCc3ccccc3)=C2[O-])C=C1Oc1ccccc1] | 591 nm (APC) |
| I-15 | 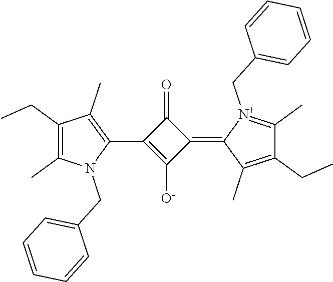 [SMILES: CCC1=C(C)/C(=C2/C(=O)C(c3c(C)c(CC)c(C)n3Cc3ccccc3)=C2[O-])[N+](Cc2ccccc2)=C1C] | 595 nm (APC) |
| I-16 | 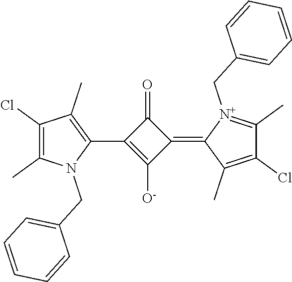 [SMILES: CC1=C(Cl)C(C)=[N+](Cc2ccccc2)/C1=C1\C(=O)C(c2c(C)c(Cl)c(C)n2Cc2ccccc2)=C1[O-]] | 595 nm (APC) |
| I-17 | 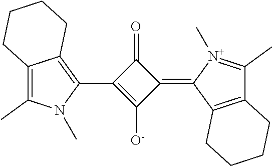 | 596 nm (APC) |
| I-18 | 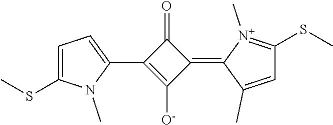 | 614 nm (APC) |
| I-19 | 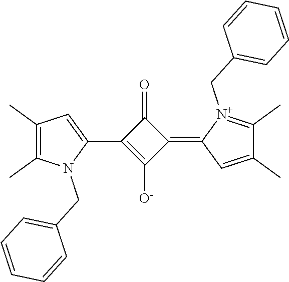 [SMILES: CC1=C/C(=C2/C(=O)C(c3cc(C)c(C)n3Cc3ccccc3)=C2[O-])[N+](Cc2ccccc2)=C1C] | 581 nm (APC) |
| I-20 | 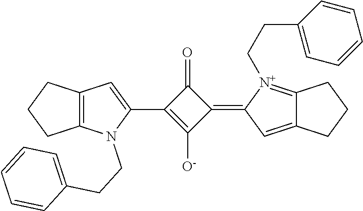 [SMILES: O=C1C(c2cc3c(n2CCc2ccccc2)CCC3)=C([O-])/C1=C1\C=C2CCCC2=[N+]1CCc1ccccc1] | 591 nm (APC) |
| I-21 | 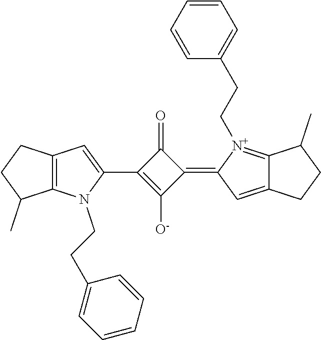 [SMILES: CC1CCC2=C/C(=C3/C(=O)C(c4cc5c(n4CCc4ccccc4)C(C)CC5)=C3[O-])[N+](CCc3ccccc3)=C21] | 593 nm (APC) |
| I-22 | 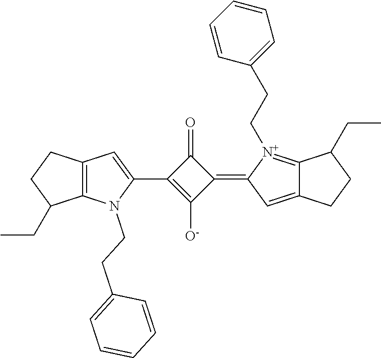 [SMILES: CCC1CCC2=C/C(=C3/C(=O)C(c4cc5c(n4CCc4ccccc4)C(CC)CC5)=C3[O-])[N+](CCc3ccccc3)=C21] | 594 nm (APC) |
| I-23 | 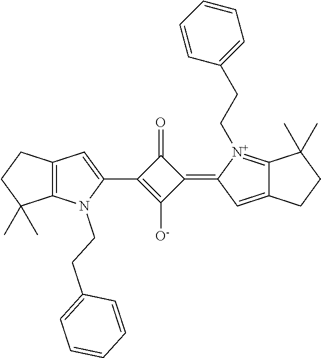 [SMILES: CC1(C)CCC2=C/C(=C3/C(=O)C(c4cc5c(n4CCc4ccccc4)C(C)(C)CC5)=C3[O-])[N+](CCc3ccccc3)=C21] | 594 nm (APC) |
| I-24 | 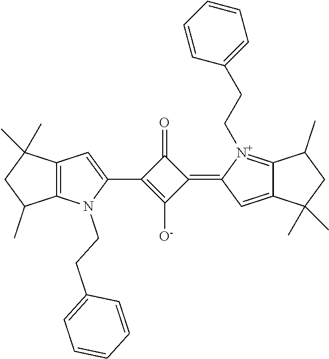 | 592 nm |
| I-25 | 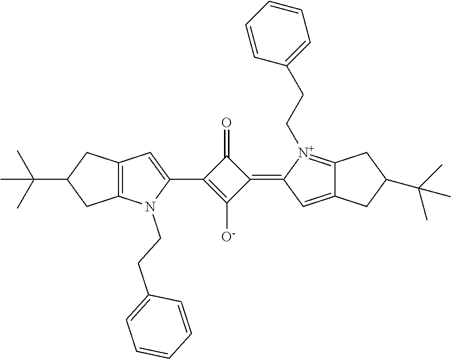 [SMILES: CC(C)(C)C1CC2=C/C(=C3/C(=O)C(c4cc5c(n4CCc4ccccc4)CC(C(C)(C)C)C5)=C3[O-])[N+](CCc3ccccc3)=C2C1] | 593 nm |
| I-26 | 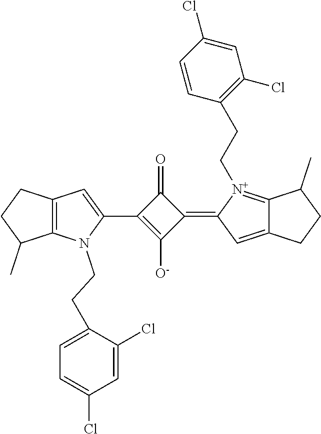 [SMILES: CC1CCC2=C/C(=C3/C(=O)C(c4cc5c(n4CCc4ccc(Cl)cc4Cl)C(C)CC5)=C3[O-])[N+](CCc3ccc(Cl)cc3Cl)=C21] | 594 nm |
| I-27 | 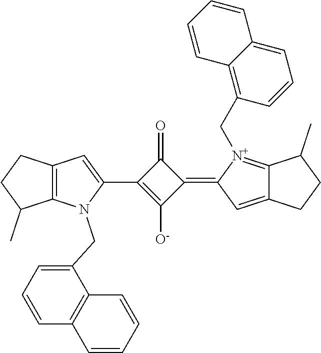 [SMILES: CC1CCC2=C/C(=C3/C(=O)C(c4cc5c(n4Cc4cccc6ccccc46)C(C)CC5)=C3[O-])[N+](Cc3cccc4ccccc34)=C21] | 594 nm |
| II-1 | 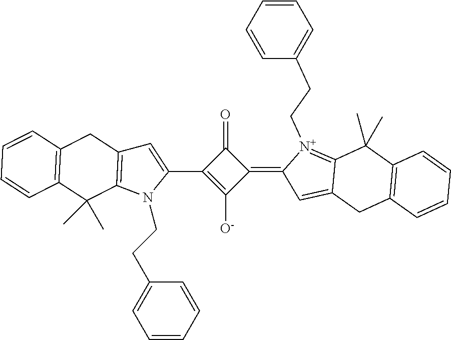 [SMILES: CC1(C)C2=[N+](CCc3ccccc3)/C(=C3\C(=O)C(c4cc5c(n4CCc4ccccc4)C(C)(C)c4ccccc4C5)=C3[O-])C=C2Cc2ccccc21] | 597 nm |

The compound x satisfying the relationship described in the foregoing is effective in widening the color gamut of an image display apparatus because the compound can absorb light emitted from a light source, the light being not needed for color representation, to suppress the light emission. In addition, the compound hardly absorbs light emitted from a light source whose wavelength is around 545 nm at which a visibility is high, and hence can suppress a reduction in brightness of the apparatus. The absorption spectrum of the compound X is measured with a spectrophotometer (U-4100 manufactured by Hitachi High-Technologies Corporation).

The content of the compound in the optical pressure-sensitive adhesive sheet is adjusted by the extinction coefficient of the compound X and the kind of the base polymer, such as the (meth)acrylic polymer. In normal cases, the content is preferably from 0.01 part by weight to 5 parts by weight, more preferably from 0.05 part by weight to 1 part by weight, still more preferably from 0.1 part by weight to 0.5 part by weight with respect to 100 parts by weight of the base polymer.

### A-4. Cross-Linking Agent

Further, in the present invention, a cross-linking agent may be incorporated into the pressure-sensitive adhesive composition for forming the pressure-sensitive adhesive layer containing the compound X. An organic cross-linking agent or a polyfunctional metal chelate may be used as the cross-linking agent. Examples of the organic cross-linking agent include an isocyanate-based cross-linking agent, an epoxy-based cross-linking agent, and an imine-based cross-linking agent. The polyfunctional metal chelate is such that a polyvalent metal atom is covalently bonded or coordinated to an organic compound. Examples of the polyvalent metal atom include Al, Cr, Zr, Co, Cu, Fe, Ni, V, Zn, In, Ca, Mg, Mn, Y, Ce, Sr, Ba, Mo, La, Sn, and Ti. An atom in the organic compound to which the polyvalent metal atom is covalently bonded or coordinated is, for example, an oxygen atom, and examples of the organic compound include an alkyl ester, an alcohol compound, a carboxylic acid compound, an ether compound, and a ketone compound.

Examples of a compound according to the isocyanate-based cross-linking agent may include: isocyanate monomers, such as tolylene diisocyanate, chlorophenylene diisocyanate, tetramethylene diisocyanate, xylylene diisocyanate, diphenylmethane diisocyanate, and hydrogenated diphenylmethane diisocyanate; isocyanate compounds each obtained by addition of those isocyanate monomers to trimethylolpropane or the like; isocyanurated products; biuret-type compounds; and urethane prepolymer-type isocyanates each obtained by an addition reaction with polyether polyol, polyester polyol, acrylic polyol, polybutadiene polyol, and polyisoprene polyol. Of those, a polyisocyanate compound formed of one kind selected from the group consisting of hexamethylene diisocyanate, hydrogenated xylylene diisocyanate, and isophorone diisocyanate, or a polyisocyanate compound derived therefrom is particularly preferred. Herein, examples of the polyisocyanate compound formed of one kind selected from the group consisting of hexamethylene diisocyanate, hydrogenated xylylene diisocyanate, and isophorone diisocyanate, or the polyisocyanate compound derived therefrom include hexamethylene diisocyanate, hydrogenated xylylene diisocyanate, isophorone diisocyanate, a polyol-modified hexamethylene diisocyanate, a polyol-modified hydrogenated xylylene diisocyanate, a trimer-type hydrogenated xylylene diisocyanate, and a polyol-modified isophorone diisocyanate. Each of the exemplified polyisocyanate compounds is preferred because its reaction with a hydroxyl group rapidly advances through the use of, in particular, an acid or abase in the polymer like a catalyst, and hence contributes, in particular, to the fast cross-linking of the pressure-sensitive adhesive composition.

The usage amount of the cross-linking agent is preferably 20 parts by weight or less, more preferably from 0.01 part by weight to 20 parts by weight, still more preferably from 0.03 part by weight to 10 parts by weight with respect to 100 parts by weight of the base polymer, such as the (meth)acrylic polymer, in the pressure-sensitive adhesive composition. When the usage amount of the cross-linking agent is more than 20 parts by weight, the moisture resistance of the optical pressure-sensitive adhesive sheet is not sufficient, and hence the peeling thereof is liable to occur in a reliability test or the like.

The optical pressure-sensitive adhesive sheet containing the compound X is formed from the pressure-sensitive adhesive composition. At the time of the formation of the pressure-sensitive adhesive sheet, it is preferred that the influences of the cross-linking treatment temperature and cross-linking treatment time of the composition be sufficiently considered together with the adjustment of the addition amount of the cross-linking agent.

The cross-linking treatment temperature and the cross-linking treatment time may be adjusted by the cross-linking agent to be used. The cross-linking treatment temperature is preferably 170° C. or less.

In addition, such cross-linking treatment may be performed at a temperature at the time of a step of drying the pressure-sensitive adhesive sheet, or may be performed by separately arranging a cross-linking treatment step after the drying step.

In addition, the cross-linking treatment time, which may be set in consideration of productivity and workability, is typically from about 0.2 minute to about 20 minutes, preferably from about 0.5 minute to about 10 minutes.

### A-5. Method of Producing Optical Pressure-Sensitive Adhesive Sheet

As a method of forming the pressure-sensitive adhesive sheet containing the compound X, an optical pressure-sensitive adhesive sheet with a separator may be obtained by, for example, applying the pressure-sensitive adhesive composition to a release-treated separator or the like, drying and removing its polymerization solvent or the like to form a pressure-sensitive adhesive sheet, and then arranging another separator on the surface of the pressure-sensitive adhesive sheet on which the separator is absent.

A silicone release liner is preferably used as the release-treated separator. An appropriate method may be appropriately adopted in accordance with a purpose as a method of drying the pressure-sensitive adhesive composition of the present invention in the process in which the pressure-sensitive adhesive composition of the present invention is applied onto such liner and dried to form the pressure-sensitive adhesive layer. A method including heating and drying the applied film of the composition is preferably used. The temperature at which the applied film is heated and dried is preferably from 40° C. to 200° C., more preferably from 50° C. to 180° C., particularly preferably from 70° C. to 170° C. When the heating temperature is set within the ranges, a pressure-sensitive adhesive having an excellent pressure-sensitive adhesive characteristic can be obtained.

An appropriate time may be appropriately adopted as the drying time of the applied film. The drying time is preferably from 5 seconds to 20 minutes, more preferably from 5 seconds to 10 minutes, particularly preferably from 10 seconds to 5 minutes.

Any of various methods is used as a method of forming the pressure-sensitive adhesive layer on the separator for obtaining the pressure-sensitive adhesive sheet. Specific examples thereof include methods using roll coating, kiss roll coating, gravure coating, reverse coating, roll brushing, spray coating, dip roll coating, bar coating, knife coating, air knife coating, curtain coating, lip coating, and an extrusion coating method using a die coater or the like.

The thickness of the pressure-sensitive adhesive layer is not particularly limited, and is, for example, about 1 μm or more and about 100 μm or less. The lower limit of the thickness of the pressure-sensitive adhesive layer is preferably 2 μm or more, more preferably 5 μm or more. Meanwhile, the upper limit of the thickness of the pressure-sensitive adhesive layer is preferably 50 μm or less, more preferably 40 μm or less, still more preferably 35 μm or less.

Examples of a constituent material for the separator may include: plastic films, such as polyethylene, polypropylene, polyethylene terephthalate, and polyester films; porous materials, such as paper, cloth, and a nonwoven fabric; and appropriate thin-leaf bodies, such as a net, a foam sheet, metal foil, and a laminated body thereof. Of those, a plastic film is suitably used because of its excellent surface smoothness.

The plastic film is not particularly limited as long as the film can protect the pressure-sensitive adhesive layer, and examples thereof include a polyvinyl alcohol film, a polyethylene film, a polypropylene film, a polybutene film, a polybutadiene film, a polymethylpentene film, a polyvinyl chloride film, a vinyl chloride copolymer film, a polyethylene terephthalate film, a polybutylene terephthalate film, a polyurethane film, and an ethylene-vinyl acetate copolymer film.

The thickness of the separator is typically from about 5 μm to about 200 μm, preferably from about 5 μm to about 100 μm. The separator may be subjected to release and anticontamination treatments with, for example, a silicone-based, fluorine-based, long-chain alkyl-based, or fatty acid amide-based release agent, or silica powder, or an antistatic treatment of, for example, an application type, a kneading type, or a vapor deposition type as required. In particular, when the surface of the separator is appropriately subjected to a release treatment, such as a silicone treatment, a long-chain alkyl treatment, or a fluorine treatment, the peelability of the separator from the pressure-sensitive adhesive layer can be further improved.

B. Polarizing Film with Pressure-sensitive Adhesive Layer

The polarizing film with a pressure-sensitive adhesive layer that is one aspect of the optical film of the present invention is described.

The polarizing film of the present invention includes the polyvinyl alcohol-based polarizer. A mode for the formation of a pressure-sensitive adhesive layer is, for example, a method including: applying the pressure-sensitive adhesive composition containing the base polymer and the compound X described in detail in the section “A. Color Correction Member” to the polarizing film including the polyvinyl alcohol-based polarizer; and drying and removing its polymerization solvent or the like to form the pressure-sensitive adhesive layer on the polarizing film including the polyvinyl alcohol-based polarizer. At the time of the application of the pressure-sensitive adhesive composition, one or more kinds of solvents except the polymerization solvent may be appropriately added anew. In addition, another mode for the formation of the pressure-sensitive adhesive layer is, for example, a transfer method including bonding the pressure-sensitive adhesive sheet described in detail in the section “A. Color Correction Member” to the polarizing film including the polyvinyl alcohol-based polarizer to provide a polarizing film with a pressure-sensitive adhesive layer.

In addition, an anchor layer (having a thickness of, for example, from about 0.5 μm to about 2 μm) may be formed on the surface of the polarizing film including the polyvinyl alcohol-based polarizer, or the pressure-sensitive adhesive layer may be formed through application or transfer after the surface has been subjected to various easy-adhesion treatments, such as a corona treatment and a plasma treatment. In addition, the surface of the pressure-sensitive adhesive layer may be subjected to an easy-adhesion treatment.

The pressure-sensitive adhesive layer of the polarizing film with a pressure-sensitive adhesive layer has an absorption peak at from 580 nm to 610 nm of its absorption spectrum, and when the value of the highest absorption peak at from 580 nm to 610 nm of the absorption spectrum is represented by Aₘₐₓ, and the value of the absorbance at 545 nm of the absorption spectrum is represented by A₅₄₅, the ratio A₅₄₅/Aₘₐₓ satisfies a relationship of A₅₄₅/Aₘₐₓ≤0.13. The absorption spectrum is obtained by: dispersing or dissolving the pressure-sensitive adhesive layer in an organic solvent to prepare a dispersion liquid or a solution; and measuring the absorbance of the dispersion liquid or the solution in the range of from 400 nm to 700 nm. The pressure-sensitive adhesive layer is preferably free of an absorption peak in the range of from 530 nm to 570 nm of the absorption spectrum. More specifically, the pressure-sensitive adhesive layer is free of an absorption peak having an absorbance of 0.1 or more in the range of from 530 nm to 570 nm. In addition, from the viewpoint of further widening of the color gamut of an image display apparatus, the half width of the absorption peak that the pressure-sensitive adhesive layer has at from 580 nm to 610 nm of the absorption spectrum is more preferably 35 nm or less.

In normal cases, a polarizing film including a transparent protective film on one surface, or each of both surfaces, of the polyvinyl alcohol-based polarizer is generally used as the polarizing film.

The polyvinyl alcohol-based polarizer is not particularly limited, and various polarizers may each be used. Examples of the polarizer include polyene-based alignment films, such as: a product obtained by causing a hydrophilic polymer film, such as a polyvinyl alcohol-based film, a partially formalized polyvinyl alcohol-based film, or an ethylene-vinyl acetate copolymer-based partially saponified film, to adsorb a dichroic substance, such as iodine or a dichroic dye, and uniaxially stretching the resultant; a dehydration-treated product of polyvinyl alcohol; and a dehydrochlorination-treated product of polyvinyl chloride. Of those, a polarizer formed of a polyvinyl alcohol-based film and a dichroic substance, such as iodine, is suitable. The thickness of such polarizer, which is not particularly limited, is generally about 80 μm or less.

A polarizer obtained by dyeing the polyvinyl alcohol-based film with iodine and uniaxially stretching the dyed film may be produced by, for example, immersing the polyvinyl alcohol-based film in an aqueous solution of iodine to dye the film, and stretching the dyed film so that the film may have a length 3 to 7 times as long as its original length. The film may be immersed in an aqueous solution of, for example, potassium iodide, which may contain boric acid, zinc sulfate, zinc chloride, or the like, as required. Further, the polyvinyl alcohol-based film may be washed with water by being immersed in the water before the dyeing as required. When the polyvinyl alcohol-based film is washed with water, contamination and an antiblocking agent on the surface of the polyvinyl alcohol-based film can be washed off. Moreover, the following effect is obtained: the polyvinyl alcohol-based film is swollen to prevent its non-uniformity, such as dyeing unevenness. The stretching may be performed after the dyeing with iodine, the stretching may be performed while the dyeing is performed, or the dyeing with iodine may be performed after the stretching. The stretching may be performed in an aqueous solution of, for example, boric acid or potassium iodide, or in a water bath.

In addition, the thickness of the polarizer is not particularly limited, and is typically 30 μm or less. From the viewpoint of thinning, the upper limit of the thickness of the polarizer is preferably 10 μm or less, more preferably 7 μm or less. Meanwhile, the lower limit thereof is 1 μm or more. Such thin polarizer is preferred because of the following reasons: the polarizer is reduced in thickness unevenness; the polarizer is excellent in viewability; the polarizer is reduced in dimensional changes, and is hence excellent in durability; and the thickness of the polarizer when used as a polarizing film can be reduced.

Typical examples of the thin polarizer include thin polarizing films described in JP 51-069644 A, JP 2000-338329 A, WO 2010/100917 A1, PCT/JP 2010/001460, the specification of Japanese Patent Application No. 2010-269002, and the specification of Japanese Patent Application No. 2010-263692. Any such thin polarizing film may be produced by a production method including the steps of: stretching a polyvinyl alcohol-based resin (hereinafter sometimes referred to as “PVA-based resin”) layer and a resin substrate for stretching under a state of being a laminate; and dyeing the stretched laminate. According to the production method, even when the PVA-based resin layer is thin, the layer is supported by the resin substrate for stretching, and hence the stretching can be performed without a trouble due to the stretching, such as rupture.

The thin polarizing film is preferably a polarizing film obtained by such a production method as described in WO 2010/100917 A1, PCT/JP 2010/001460, or the specification of Japanese Patent Application No. 2010-269002 or the specification of Japanese Patent Application No. 2010-263692, the production method including the step of stretching the layer and the substrate in an aqueous solution of boric acid, out of the production methods each including the step of stretching the layer and the substrate under a state of being a laminate, and the step of dyeing the stretched laminate because the stretching can be performed at a high ratio, and hence the polarization performance of the polarizing film can be improved. A polarizing film obtained by a production method described in the specification of Japanese Patent Application No. 2010-269002 or the specification of Japanese Patent Application No. 2010-263692, the production method including the step of auxiliary subjecting the laminate to in-air stretching before the stretching in the aqueous solution of boric acid, is particularly preferred.

As a material for forming the transparent protective film, for example, a thermoplastic resin excellent in transparency, mechanical strength, heat stability, moisture blocking property, isotropy, and the like is used. Specific examples of such thermoplastic resin include a cellulose resin, such as triacetyl cellulose, a polyester resin, a polyethersulfone resin, a polysulfone resin, a polycarbonate resin, a polyamide resin, a polyimide resin, a polyolefin resin, a (meth)acrylic resin, a cyclic polyolefin resin (a norbornene-based resin), a polyarylate resin, a polystyrene resin, a polyvinyl alcohol resin, and mixtures thereof. The transparent protective film is bonded to one surface of the polarizer via an adhesive layer, and on the other surface, for example, a (meth)acrylic, urethane-based, acrylic urethane-based, epoxy-based, or silicone-based thermosetting resin or UV-curable resin may be used as a transparent protective film. The transparent protective film may contain one or more kinds of any appropriate additives. Examples of the additive include a UV absorbing agent, an antioxidant, a lubricant, a plasticizer, a release agent, a coloring preventing agent, a flame retardant, a nucleating agent, an antistatic agent, a pigment, and a colorant. The content of the thermoplastic resin in the transparent protective film is preferably from 50 wt % to 100 wt %, more preferably from 50 wt % to 99 wt %, still more preferably from 60 wt % to 98 wt %, particularly preferably from 70 wt % to 97 wt %. When the content of the thermoplastic resin in the transparent protective film is 50 wt % or less, there is a risk in that high transparency or the like intrinsic to the thermoplastic resin cannot be sufficiently expressed.

The thickness of the transparent protective film is not particularly limited, and is, for example, from about 10 μm to about 90 μm. The thickness is preferably from 15 μm to 60 μm, more preferably from 20 μm to 50 μm.

An adhesive to be used in the bonding of the polarizer and the transparent protective film is not particularly limited as long as the adhesive is optically transparent, and adhesives of various forms, such as an aqueous adhesive, a solvent-based adhesive, a hot melt-type adhesive, a radical-curable adhesive, and a cation-curable adhesive, are each used. Of those, an aqueous adhesive or a radical-curable adhesive is suitable.

C. Liquid Crystal Panel

The polarizing film with a pressure-sensitive adhesive layer of the present invention is bonded to at least one surface of a liquid crystal cell via the pressure-sensitive adhesive layer of the polarizing film with a pressure-sensitive adhesive layer to form a liquid crystal panel. The polarizing film with a pressure-sensitive adhesive layer of the present invention is suitably used for the viewer side of the liquid crystal cell.

Although a liquid crystal cell of any type, such as a TN type, a STN type, a n type, a VA type, or an IPS type, may be used as the liquid crystal cell, a liquid crystal cell of an IPS mode is suitably used in the liquid crystal panel of the present invention.

In addition to the polarizing film, any other optical layer may be applied to the formation of the liquid crystal panel. Although the optical layer is not particularly limited, one or two or more optical layers that may be used in the formation of the liquid crystal panel, such as a reflective plate, a semi-transmissive plate, a retardation plate (including a wavelength plate, such as a ½-wavelength plate or a ¼-wavelength plate), a viewing angle compensation film, and a brightness enhancement film, may be used on the viewer side and/or back surface side of the liquid crystal cell.

D. Liquid Crystal Display Apparatus

The liquid crystal panel is used in a liquid crystal display apparatus, and the apparatus is formed by, for example, appropriately assembling a constituent part, such as alighting system, as required, and incorporating a driver circuit into the part. Further, at the time of the formation of the liquid crystal display apparatus, one or two or more appropriate parts, such as a diffusing plate, an antiglare layer, an antireflection film, a protective plate, a prism array, a lens array sheet, a light-diffusing plate, and a backlight, may be arranged at appropriate positions. In addition, an appropriate liquid crystal display apparatus, such as a liquid crystal display apparatus using a backlight or a reflective plate in its lighting system, may be formed.

### EXAMPLES

The present invention is specifically described below by way of Examples, but the present invention is not limited to these Examples. In Examples, “part(s)” and “%” are by weight. All of the following room-temperature standing conditions are 23° C. and 65% RH unless otherwise stated.

<Measurement of Absorption Spectrum and Absorbance>

To identify the absorption peaks and absorbances of the color correction member, and the pressure-sensitive adhesive layer of the polarizing film with a pressure-sensitive adhesive layer, of the present invention, absorption spectrum measurement is performed by the following approach.

An organic solvent, such as ethyl acetate or toluene, is used as a solvent, and the color correction member or the pressure-sensitive adhesive layer of the polarizing film with a pressure-sensitive adhesive layer is dissolved or dispersed in the solvent to prepare a measurement sample.

The absorption spectrum and absorbance of the measurement sample are measured with a spectrophotometer (U-4100 manufactured by Hitachi High-Technologies Corporation).

The value of the ratio A₅₄₅/Aₘₐₓ is obtained through calculation after the value Aₘₐₓ of an absorption peak at from 580 nm to 610 nm of the absorption spectrum has been normalized to 1, and the value A₅₄₅ of an absorbance at 545 nm of the absorption spectrum has been calculated.

<Methods of Measuring Brightness and Color Gamut>

A liquid crystal panel (liquid crystal panel including a liquid crystal cell of an IPS mode) was removed from a liquid crystal television (43UF7710) manufactured by LG Electronics Incorporated. Further, a polarizing film with a pressure-sensitive adhesive layer on a viewer side was removed from the liquid crystal cell.

A polarizing film (P1) with a pressure-sensitive adhesive layer produced in each of Examples and Reference Examples was bonded to the viewer side of the liquid crystal cell from which the polarizing film with a pressure-sensitive adhesive layer had been removed. Thus, a liquid crystal panel (C1) was produced.

Each of the produced liquid crystal panels (C1) was returned to the liquid crystal television. After that, in a dark room, the measurement site of the liquid crystal television was caused to display white, red, blue, and green colors, and the brightnesses and chromaticities (x, y) of the colors were measured with a luminance colorimeter (SR-UL1 manufactured by Topcon Technohouse Corporation) under the same backlight condition. Then, the area of a triangle formed by connecting the chromaticity coordinates of the respective simple colors (R, G, and B) was calculated, and the area of a region where the triangle and the color gamut standard of DCI overlapped each other was calculated, followed by the calculation of the ratio (DCI ratio) of the area of the region to the original area.

<Measurement of Weight-Average Molecular Weight of (Meth)acrylic Polymer>

The weight-average molecular weight (Mw) of a (meth)acrylic polymer was measured by gel permeation chromatography (GPC). The Mw/Mn thereof was also measured in the same manner.

Analysis device: HLC-8120GPC manufactured by Tosoh Corporation

Column: G7000H_{XL}+GMH_{XL}+GMH_{XL} manufactured by Tosoh Corporation

Column size: 7.8 mmφ×30 cm each, total: 90 cm

Column temperature: 40° C.

Flow rate: 0.8 mL/min

Injection amount: 100 μL

Eluent: tetrahydrofuran

Detector: differential refractometer (RI)

Standard sample: polystyrene

### Example 1

### <Production of Polarizing Film>

To produce a thin polarizing layer, first, a laminate having a 9-micrometer thick PVA layer formed on an amorphous PET substrate was subjected to in-air auxiliary stretching at a stretching temperature of 130° C. to produce a stretched laminate. Next, the stretched laminate was dyed to produce a colored laminate. Further, the colored laminate was stretched in boric acid water at a stretching temperature of 65° C. so that a total stretching ratio became 5.94 times. Thus, an optical film laminate including a 4-micrometer thick PVA layer stretched integrally with the amorphous PET substrate was produced. Such two-stage stretching was able to produce an optical film laminate including the 4-micrometer thick PVA layer forming a high-functionality polarizing layer, in which the PVA molecules of the PVA layer formed on the amorphous PET substrate were aligned in a high order; and iodine adsorbed by the PVA molecules through the dyeing was aligned as a polyiodide ion complex in one direction in a high order. Further, while a polyvinyl alcohol-based adhesive was applied to the surface of the polarizing layer of the optical film laminate, a 40-micrometer thick acrylic resin film subjected to a saponification treatment was bonded to the surface, followed by the peeling of the amorphous PET substrate. While a polyvinyl alcohol-based adhesive was similarly applied to the surface of the polarizing layer from which the substrate had been peeled, a 40-micrometer thick acrylic resin film subjected to a saponification treatment was bonded to the surface. Thus, a polarizing film using a thin polarizer was produced. The film is referred to as “thin polarizing film”.

<Preparation of (Meth)acrylic Polymer>

A monomer mixture containing 100 parts of butyl acrylate, 0.01 part of 2-hydroxyethyl acrylate, and 5 parts of acrylic acid was loaded into a reaction vessel including a condenser, a nitrogen-introducing tube, a temperature gauge, and a stirring apparatus. Further, 0.1 part of 2,2′-azobisisobutyronitrile serving as a polymerization initiator was loaded into 100 parts of the monomer mixture together with 100 parts of ethyl acetate. While the mixture was gently stirred, a nitrogen gas was introduced into the vessel to purge air in the vessel with nitrogen. After that, the temperature of the liquid in the vessel was kept at around 55° C., and a polymerization reaction was performed for 8 hours to prepare a solution (solid content concentration: 30 wt %) of an acrylic polymer having a weight-average molecular weight (Mw) of 1,800,000 and an Mw/Mn of 4.1.

<Preparation of Pressure-Sensitive Adhesive Composition>

100 Parts of the solid content of the acrylic polymer solution produced in the foregoing was compounded with 1 part of an isocyanate-based cross-linking agent (available under the product name“CORONATE L” from Tosoh Corporation) and 0.25 part of a squaraine compound represented by the following chemical formula (I-2) obtained in Synthesis Example 1 to provide a pressure-sensitive adhesive composition.

The squaraine compound represented by the chemical formula (I-2) was synthesized by the synthesis method described in “This compound was made in a manner similar to a published procedure: J. Chem. Soc., Perkin Trans. 2, 1998, 779.”

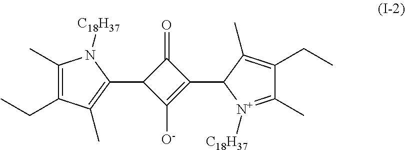

<Production of Polarizing Film with Pressure-Sensitive Adhesive Layer>

The pressure-sensitive adhesive composition was uniformly applied to the surface of one acrylic resin film of the thin polarizing film with an applicator, and was dried in an air circulation-type thermostatic oven at 155° C. for 2 minutes to form, on the surface of the polarizer, a 20-micrometer thick pressure-sensitive adhesive layer containing the squaraine compound represented by the chemical formula (I-2). Thus, a polarizing film with a pressure-sensitive adhesive layer was produced.

The pressure-sensitive adhesive layer of the resultant polarizing film with a pressure-sensitive adhesive layer was dissolved in ethyl acetate, and the solution was diluted, followed by the measurement of its absorption spectrum. The absorption spectrum had an absorption peak at a wavelength of 586 nm, and the absorption peak had a half width of 27 nm. In addition, in the absorption spectrum, when the value Aₘₐₓ of the absorption peak at a wavelength of 586 nm was normalized to 1, the value of the absorbance A₅₄₅ at a wavelength of 545 nm was 0.13. Thus, the ratio A₅₄₅/Aₘₐₓ was 0.13.

### Example 2

A polarizing film with a pressure-sensitive adhesive layer was obtained in the same manner as in Example 1 except that the squaraine compound represented by the chemical formula (I-27) was used instead of the squaraine compound represented by the chemical formula (I-2).

The squaraine compound represented by the chemical formula (I-27) was synthesized by the following method.

### <Synthesis of Squaraine Compound>

Under an argon atmosphere, 0.42 g of 2-methylcyclopentanone was dissolved in 10 mL of 1-methylcyclohexanol. 0.74 Gram of 1-naphthylmethylamine was added to the resultant solution, and the solution was heated in an oil bath at 80° C. for 40 minutes. Next, 26 mg of dichloro(p-cymene)ruthenium(II) dimer, 50 mg of xantphos, and 0.53 mL of ethylene glycol were added to the solution, and the mixture was heated at 145° C. for 24 hours. Next, the residue was purified by using silica gel chromatography based on an ethyl acetate-hexane gradient. Thus, 180 mg of a pyrrole product was obtained. The product was dissolved in 2.5 mL of ethanol, and 39 mg of squaric acid was added to the solution, followed by heating at 80° C. for 2.5 hours. The resultant slurry was cooled, and the product was filtered out. The product that had been filtered out was dried under reduced pressure at 75° C. to provide 148 mg of the squaraine compound.

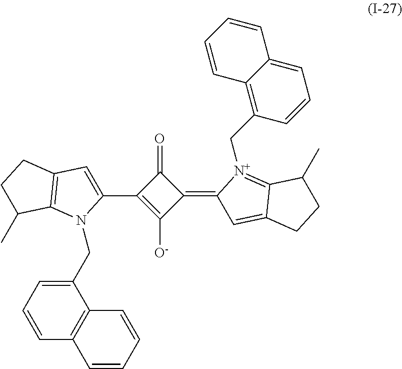 [SMILES: CC1CCC2=C/C(=C3/C(=O)C(c4cc5c(n4Cc4cccc6ccccc46)C(C)CC5)=C3[O-])[N+](Cc3cccc4ccccc34)=C21]

The pressure-sensitive adhesive layer of the resultant polarizing film with a pressure-sensitive adhesive layer was dissolved in ethyl acetate, and the solution was diluted, followed by the measurement of its absorption spectrum. The absorption spectrum had an absorption peak at a wavelength of 594 nm, and the absorption peak had a half width of 23 nm. In addition, in the absorption spectrum, when the value Aₘₐₓ of the absorption peak at a wavelength of 594 nm was normalized to 1, the value of the absorbance A₅₄₅ at a wavelength of 545 nm was 0.10. Thus, the ratio A₅₄₅/Aₘₐₓ was 0.10.

### Reference Example 1

A polarizing film with a pressure-sensitive adhesive layer was produced in the same manner as in Example 1 except that a porphyrin-based coloring matter (available under the product name “PD-320” from Yamamoto Chemicals, Inc.) was used instead of the squaraine compound represented by the chemical formula (I-2).

The absorption spectrum of the pressure-sensitive adhesive layer was measured in the same manner as in Example 1. The absorption spectrum had an absorption peak at a wavelength of 595 nm, and the absorption peak had a half width of 25 nm. In addition, in the absorption spectrum, when the value Aₘₐₓ of the absorption peak at a wavelength of 595 nm was normalized to 1, the value of the absorbance A₅₄₅ at a wavelength of 545 nm was 0.16. Thus, the ratio A₅₄₅/Aₘₐₓ was 0.16.

### Reference Example 2

A polarizing film with a pressure-sensitive adhesive layer was produced in the same manner as in Example 1 except that the squaraine compound represented by the chemical formula (I-2) was not added.

The evaluation results of Examples 1 and 2, and Reference Examples 1 and 2 are shown in Table 1.

TABLE 1

| | Brightness | Color gamut | Absorption | Half |
|---|---|---|---|---|
| | (cd/m²) | (DCI ratio) | peak | width |
| Example 1 | 265 | 87.8% | 586 nm | 27 nm |
| Example 2 | 279 | 86.2% | 594 nm | 23 nm |
| Reference | 257 | 86.2% | 595 nm | 25 nm |
| Example 1 | | | | |
| Reference | 354 | 81.8% | — | — |
| Example 2 | | | | |

According to the evaluation results of Table 1, it is found that the polarizing film using the color correction member of the present invention has a color gamut-widening function more satisfactory than that of Reference Example 2, which is a related-art polarizing film with a pressure-sensitive adhesive layer free of a color correction function, when turned into an image display apparatus. It is also found that as compared to Reference Example 1, which is a polarizing film with a pressure-sensitive adhesive layer having a conventional color gamut-widening function, the color gamut-widening function of the above-mentioned polarizing film is improved, and moreover, the polarizing film can improve the brightness of the apparatus.

1. A color correction member, characterized in that, when a value of an absorption peak at from 580 nm to 610 nm of an absorption spectrum is represented by Aₘₐₓ, and a value of an absorbance at 545 nm of the absorption spectrum is represented by A₅₄₅, a ratio A₅₄₅/Aₘₐₓ satisfies a relationship Of A₅₄₅/Aₘₐₓ≤0.13,
provided that the absorption spectrum is obtained by: dispersing or dissolving the color correction member in an organic solvent to prepare a dispersion liquid or a solution; and measuring an absorbance of the dispersion liquid or the solution in a range of from 400 nm to 700 nm.

2. The color correction member according to claim 1, wherein the color correction member is free of an absorption peak at from 530 nm to 570 nm of the absorption spectrum.

3. The color correction member according to claim 1, wherein the absorption peak that the color correction member has at from 580 nm to 610 nm has a half width of 35 nm or less.

4. The color correction member according to claim 1, wherein the color correction member contains a compound represented by the following formula (I) or (II): 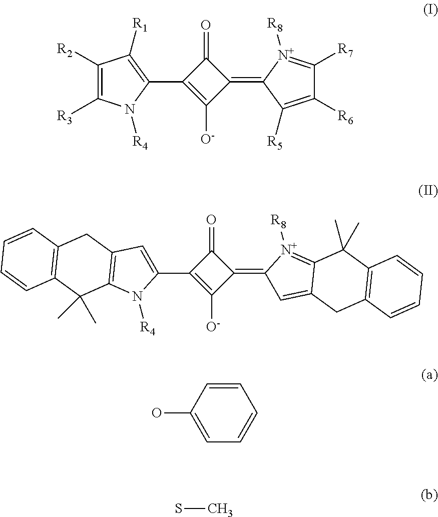
in the formula (I),
R₁, R₂, R₃, R₄, R₅, R₆, R₇, and R₈ each independently represent a hydrogen atom, a halogen atom, a substituted or unsubstituted alkyl group having 1 or more and 20 or less carbon atoms, a substituent represented by the formula (a), or a substituent represented by the formula (b),
R₁ and R₂ form a saturated cyclic skeleton including 5 or 6 carbon atoms, and R₃, R₄, R₅, R₆, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),
R₂ and R₃ form a saturated cyclic skeleton including 5 to 7 carbon atoms, and R₁, R₄, R₅, R₆, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),
R₅ and R₆ form a saturated cyclic skeleton including 5 or 6 carbon atoms, and R₁, R₂, R₃, R₄, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),
R₆ and R₇ form a saturated cyclic skeleton including 5 to 7 carbon atoms, and R₁, R₂, R₃, R₄, R₅, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),
R₁ and R₂ form a saturated cyclic skeleton including 5 or 6 carbon atoms, R₈ and R₆ form a saturated cyclic skeleton including 5 or 6 carbon atoms, and R₃, R₄, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b), or
R₂ and R₃ form a saturated cyclic skeleton including 5 to 7 carbon atoms, R₆ and R₇ form a saturated cyclic skeleton including 5 to 7 carbon atoms, and R₁, R₄, R₅, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b); and
in the formula (II), R₄ and R₈ each independently represent a hydrogen atom, or a substituted or unsubstituted alkyl group having 1 or more and 20 or less carbon atoms.

5. An optical film, comprising:
a polarizing film; and
a pressure-sensitive adhesive layer,
wherein when a value of a light absorption peak at from 580 nm to 610 nm of an absorption spectrum of the pressure-sensitive adhesive layer is represented by Aₘₐₓ, and a value of an absorbance at 545 nm of the absorption spectrum is represented by A₅₄₅, a ratio A₅₄₅/Aₘₐₓ satisfies a relationship Of A₅₄₅/Aₘₐₓ≤0.13,
provided that the absorption spectrum is obtained by: dispersing or dissolving the pressure-sensitive adhesive layer in an organic solvent to prepare a dispersion liquid or a solution; and measuring an absorbance of the dispersion liquid or the solution in a range of from 400 nm to 700 nm.

6. The optical film according to claim 5, wherein the pressure-sensitive adhesive layer is free of an absorption peak at from 530 nm to 570 nm of the absorption spectrum.

7. The optical film according to claim 5, wherein the absorption peak at from 580 nm to 610 nm has a half width of 35 nm or less.

8. The optical film according to claim 5, wherein the pressure-sensitive adhesive layer contains a compound represented by the following formula (I) or (II): 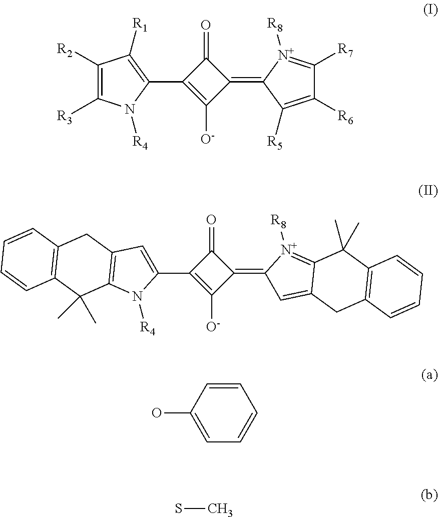
in the formula (I),
R₁, R₂, R₃, R₄, R₅, R₆, R₇, and R₈ each independently represent a hydrogen atom, a halogen atom, a substituted or unsubstituted alkyl group having 1 or more and 20 or less carbon atoms, a substituent represented by the formula (a), or a substituent represented by the formula (b),
R₁ and R₂ form a saturated cyclic skeleton including 5 or 6 carbon atoms, and R₃, R₄, R₅, R₆, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),
R₂ and R₃ form a saturated cyclic skeleton including 5 to 7 carbon atoms, and R₁, R₄, R₅, R₆, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),
R₅ and R₆ form a saturated cyclic skeleton including 5 or 6 carbon atoms, and R₁, R₂, R₃, R₄, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),
R₆ and R₇ form a saturated cyclic skeleton including 5 to 7 carbon atoms, and R₁, R₂, R₃, R₄, R₅, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b),
R₁ and R₂ form a saturated cyclic skeleton including 5 or 6 carbon atoms, R₅ and R₆ form a saturated cyclic skeleton including 5 or 6 carbon atoms, and R₃, R₄, R₇, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b), or
R₂ and R₃ form a saturated cyclic skeleton including 5 to 7 carbon atoms, R₆ and R₇ form a saturated cyclic skeleton including 5 to 7 carbon atoms, and R₁, R₄, R₅, and R₈ each independently represent a hydrogen atom, a halogen atom, which is preferably Cl, a substituted or unsubstituted alkyl group having 1 or more and 20 or less carbon atoms, a substituent represented by the formula (a), or a substituent represented by the formula (b); and
in the formula (II), R₄ and R₈ each independently represent a hydrogen atom, or a substituted or unsubstituted alkyl group having 1 or more and 20 or less carbon atoms.
